(19) United States
(12) Patent Application Publication
(10) Pub. No.: US 2025/0107456 A1
(43) Pub. Date: Mar. 27, 2025

(54) CONTACTS FOR JOSEPHSON JUNCTION-BASED QUBITS

(71) Applicant: International Business Machines Corporation, Armonk, NY (US)

(72) Inventor: Charles Thomas Rettner, San Jose, CA (US)

(21) Appl. No.: 18/475,476

(22) Filed: Sep. 27, 2023

(51) Int. Cl. H10N 60/80; H10N 60/01; H10N 60/12

(52) U.S. Cl. CPC H10N 60/805; H10N 60/0912; H10N 60/12

(57) ABSTRACT

Devices and/or computer-implemented methods facilitating improved contacts in Josephson junction-based qubits. In an embodiment, a device can comprise a superconducting capacitor pad located on top of a substrate; a contact located on a top surface of the capacitor pad, wherein the contact comprises a first contact layer comprising a superconducting material and in direct contact with the capacitor pad and a second contact layer comprising an inert conductor and that is located on top of the first contact layer; and a Josephson junction in contact with the contact.

### BACKGROUND

The subject disclosure relates to a Josephson junction-based qubit, and more specifically, to a Josephson junction-based qubit with multiple layer contacts.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, devices, and/or methods of fabrication that facilitate improved contacts in Josephson junction-based qubits are provided.

According to an embodiment, a device can comprise a superconducting capacitor pad located on top of a substrate; a contact located on a top surface of the capacitor pad, wherein the contact comprises a first contact layer comprising a superconducting material and in direct contact with the capacitor pad and a second contact layer comprising an inert conductor and that is located on top of the first contact layer; and a Josephson junction in contact with the contact. An advantage of such a device is that it allows for the formation of the Josephson junction without the need to clean the capacitor pad with ion mill prior to deposition. A further advantage of such a device is that it allows for selection of Josephson junction thickness independent of the need to cover the electrode sidewall allowing for selection of Josephson junction thicknesses that improve performance.

In one or more embodiments of the above-described device, the first contact layer can comprise a thickness greater than a thickness of the second contact layer, wherein the thickness of the second contact layer allows for super conducting of the second contact layer due to proximity of the first contact layer and the Josephson junction. An advantage of such a device is that the superconducting second contact layer will improve the performance of the qubit.

According to another embodiment, a method for fabricating a device can comprise ion milling, by a fabrication system, to expose a clean surface of an electrode of a capacitor pad; depositing, by the system, a contact on the exposed electrode, wherein the contact comprises a first contact layer comprising a superconducting material and a second contact layer comprising an inert conductor material located on top of the first contact layer; and depositing, by the fabrication system, a Josephson junction in contact with the contact. An advantage of such a method is that it allows for the deposition of the Josephson junction without the need to clean the capacitor pad with ion milling prior to deposition. A further advantage of such a method of fabrication is that it allows for selection of Josephson junction thickness independent of the need to cover the electrode, allowing for selection of Josephson junction thickness that improve performance.

In one or more embodiments of the above-described method, the first contact layer can comprise a thickness greater than a thickness of the second contact layer, and wherein the thickness of the second contact layer allows for super conducting of the second contact layer due to proximity of the first contact layer and the Josephson junction. An advantage of such a device is that the superconducting second contact layer will improve the performance of the qubit.

In one or more embodiments of the above-described method, the ion milling can comprise applying a first photoresist layer to the electrode; patterning the first photoresist layer to expose a region of the electrode, ion milling the exposed region of the electrode. An advantage of such a method is that it prevents debris and damage to the substrate on the portion where the Josephson junction will be formed, improving Josephson junction performance.

According to an embodiment, a device can comprise a first capacitor pad located on a substrate; a first contact located in direct contact with a top surface of the first capacitor pad, wherein the first contact extends from the top surface of the first capacitor pad to a top surface of the substrate; a second capacitor pad located on a substrate; a second contact located in direct contact with a top surface of the second capacitor pad, wherein the second contact extends from the top surface of the capacitor pad to the top surface of the substrate; and a Josephson junction extending from the first contact to the second contact. An advantage of such a device is that the use of contacts to cover the first capacitor pad and the second capacitor pad allows for selection of Josephson junction thickness independent of the need to cover the electrodes, allowing for selection of Josephson junction thickness that improve performance.

In one or more embodiments of the above-described device, the first contact can comprise a superconducting layer and an inert conductor layer located on top of the superconducting layer and the second contact can comprise a second superconducting layer and a second inert conductor layer located on top of the superconducting layer. An advantage of such a device is that the inert conductor materials protect the superconducting materials from oxidation during fabrication.

### DESCRIPTION OF THE DRAWINGS

FIG. 1A illustrates a cross-section view of a device 150 comprising Josephson junction in direct contact with an electrode.

FIG. 1B illustrates a cross-section view of a device comprising Josephson junction in direct contact with an electrode in accordance with one or more embodiments described herein.

FIG. 2 illustrates a starting substrate for fabrication of a device in accordance with one or more embodiments described herein.

FIG. 3 illustrates a second stage of fabrication of a device in accordance with one or more embodiments described herein.

FIG. 4 illustrates a third stage of fabrication of device in accordance with one or more embodiments described herein.

FIG. 5 illustrates a fourth stage of fabrication of device in accordance with one or more embodiments described herein.

FIG. 6 illustrates a fifth stage of fabrication of device in accordance with one or more embodiments described herein.

FIG. 7 illustrates a sixth stage of fabrication of device in accordance with one or more embodiments described herein.

FIG. 8 illustrates a top-down view of a device in accordance with one or more embodiments described herein.

FIG. 9 illustrates a top-down view of device in accordance with one or more embodiments described herein.

FIG. 10 illustrates an example qubit device with improve Josephson junction contacts in accordance with one or more embodiments described herein.

FIG. 11 illustrates a flow diagram of an example, non-limiting method of fabrication of a Josephson junction with improved contacts in accordance with one or more embodiments described herein.

FIG. 12 illustrates a flow diagram of an example, non-limiting method of fabrication of a Josephson junction with improved contacts in accordance with one or more embodiments described herein.

FIG. 13 cross-section view of a device comprising an improved contact for a Josephson junction in accordance with one or more embodiments described herein.

FIG. 14 illustrates an image of a device comprising improved contacts in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Quantum computing is generally the use of quantum-mechanical phenomena for the purpose of performing computing and information processing functions. Quantum computing can be viewed in contrast to classical computing, which generally operates on binary values with transistors. That is, while classical computers can operate on bit values that are either 0 or 1, quantum computers operate on quantum bits (qubits) that comprise superpositions of both 0 and 1, can entangle multiple quantum bits, and use interference.

Within quantum computing, Josephson junctions can be utilized as qubit elements in quantum circuits in which the junction leads are connected to the electrodes of a shunt capacitor. The physical characteristics of Josephson junctions (e.g., shape, material composition, thickness, etc.) are an important factor in quantum performance, particularly in controlling tunability of quantum elements. The Josephson junctions are commonly made by depositing the junction metal through a shallow mask so that the junction leads make contact to the electrodes of a shunt capacitor. This process utilizes ion milling prior to the deposition of the junction leads, which is limited as the ion milling damages the lithographic mask, negatively affecting the dimensional control. Further, the ion milling also creates debris and spreads unwanted material over the surface where the junction is to be formed. Accordingly, the present process requires a tradeoff between improvements in coherence from better contact obtained from longer milling of the electrode surface and the coherence losses associated with longer milling from debris. Additionally, even with sufficient ion milling, the Josephson junctions may make poor contact to the electrodes due to inadequate step coverage of the deposited fingers and the electrode sidewall. In order to cover the step, the junction deposition need to be thick and at suitable angles, which may negatively impact performance of the junction.

Given the problems described above with prior art technologies, the present disclosure can be implemented to produce a solution to these problems by fabricating multiple layer contact pads on the contact areas of the electrodes in separate steps and covering the sidewall, before fabrication of the Josephson junctions, thereby improving the connection between the junction metal and the electrodes leading to improved performance of the qubit. In one or more embodiments, the pre-fabricated contacts can comprise at least two layers, a first superconductor layer that gives good sidewall coverage and a second inert conductor layer that protects the superconductor layer from oxidation, but is made superconducting during operation by proximity to the superconductor layer and the superconducting junction lead deposited on top of the inert conductor layer. Accordingly, this approach eliminates the performance tradeoffs in existing approaches, leading to improved Josephson junction-based qubits.

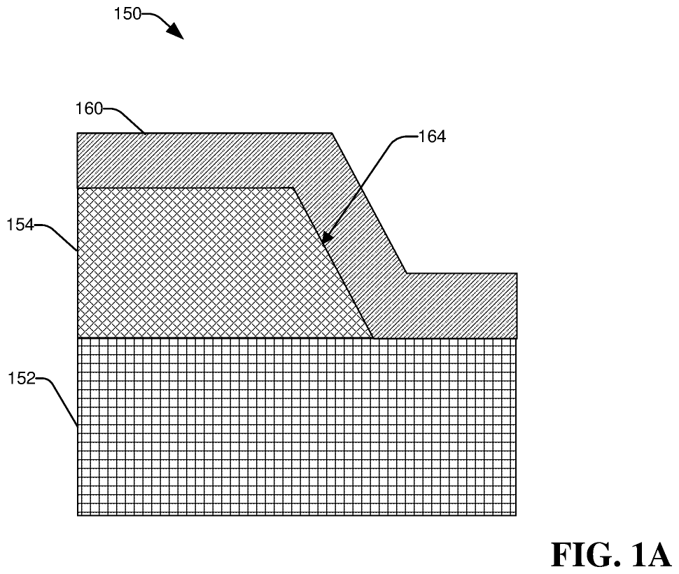

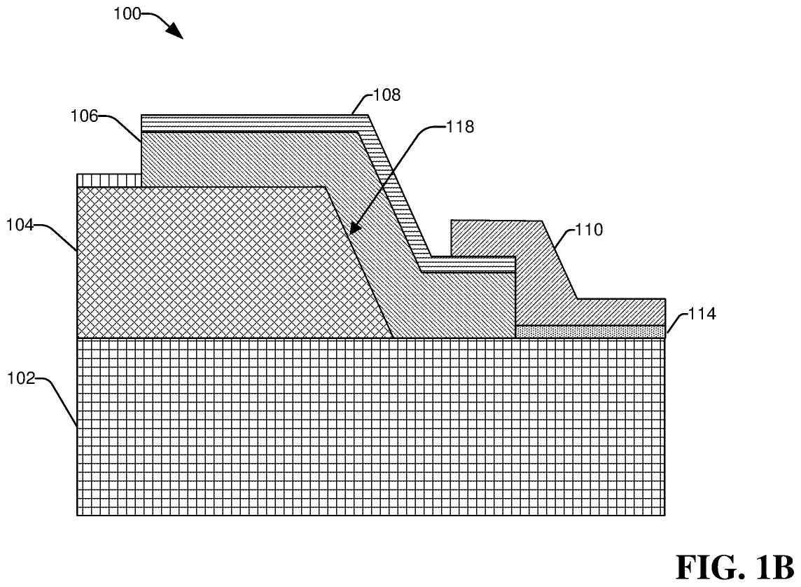

FIG. 1A illustrates a cross-section view of a device 150 comprising Josephson junction in direct contact with an electrode.

As shown in FIG. 1A. Josephson junction lead 160 is in direct contact with both electrode 154 and substrate 152. In order for sidewall 164 of electrode 154 to be adequately covered, Josephson junction lead 160 is relatively thick and at an angle, which can negatively impact performance of the Josephson junction. Further, as Josephson junction lead 160 is in direct contact with substrate 152, the ion milling used to expose a position of substrate 152 may have left debris behind that is now trapped between junction lead 160 and substrate 152, or otherwise damaged substrate 152, leading to coherence losses of junction lead 160.

FIG. 1B illustrates a cross-section view of a device 100 comprising an improved contact for a Josephson junction in accordance with one or more embodiments described herein.

As shown, device 100 comprises an electrode 104 on top of a substrate 102, a first contact layer 106 on top of electrode 104 (alternatively referred to as a capacitor pad), a second contact layer 108 on top of first contact layer 106, and a Josephson junction lead 110 in direct contact with both first contact layer 106 and second contact layer 108. As first contact layer 106 is used to cover sidewall 118 of electrode 104, the thickness of junction lead 110 can be independent of the requirement to cover electrode 104, junction thickness can be selected in order to improve performance and coherence. Further, as oxide layer 114 separates junction lead 110 from substrate 102, performance losses due to ion milling of the substrate 102 are avoided, thus improving junction performance.

In an embodiment, first contact layer 106 can comprise a superconducting material such as, but not limited to, aluminum, vanadium, titanium nitride, niobium, tantalum, or rhenium and the second contact layer 108 can comprise an inert conductor material such as, but not limited to, platinum, iridium, rhenium, gold or palladium. Additionally, junction lead 110 can comprise a superconducting material such as, but not limited to aluminum or vanadium and electrode 104 can comprise a material such as, but not limited to, niobium, tantalum, titanium nitride, niobium nitride or rhenium. Furthermore, the first contact layer can comprise a thickness greater than the thickness of second contact layer 108. Due to the second contact layer 108 being thin and placed between the superconducting layers of the first contact layer 106 and junction lead 110, the second contact layer 108 will superconduct when the device is in operation. In an embodiment, first contact layer 106 can comprise a thickness between 20 nm and 100 nm, the second contact layer 108 can comprise a thickness between 1 nm and 20 nm, and electrode 104 can comprise a thickness between 50 nm and 300 nm. Accordingly, through the use of a first contact layer and a second contact layer both issues with Josephson junction production can be addressed, allowing for the fabrication of Josephson junctions with better performance.

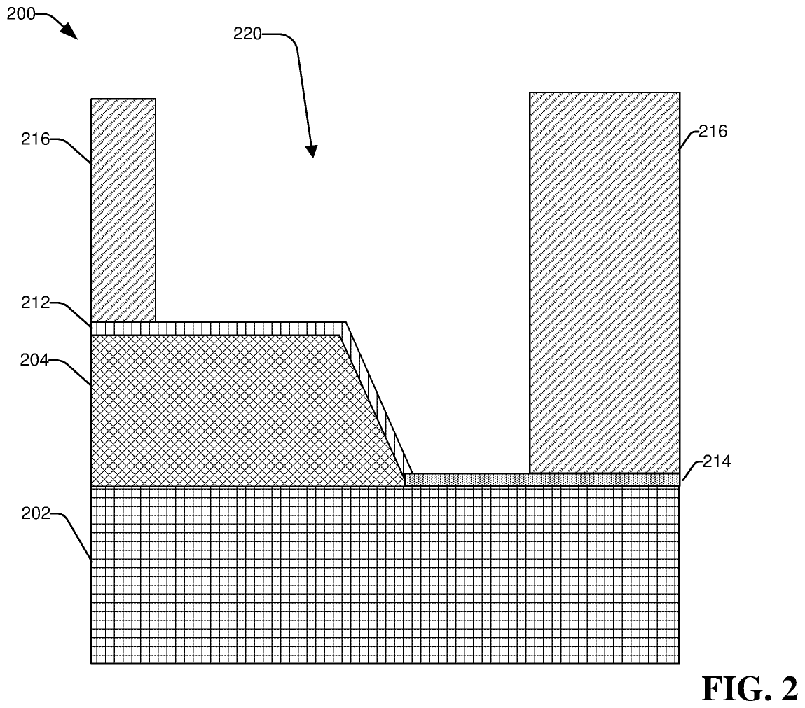

FIGS. 2-7 illustrate cross-sections of a device at various stages of fabrication in accordance with one or more embodiments described herein.

FIG. 2 illustrates a starting substrate for fabrication of a device 200 in accordance with one or more embodiments described herein. As shown, device 200 at this stage comprises a base substrate 202, an electrode 204, a first oxide mask 212 that protects electrode 204, a second oxide mask 214 that protects substrate 202, and a photoresist layer 216. A lithographic process can be utilized to form cavity 220 in photoresist layer 216 in order to expose first oxide mask 212 and second oxide mask 214. In an embodiment, first oxide mask 212 and second oxide mask 214 can comprise native oxides of the materials, such as niobium pentoxide for 212 and silicon dioxide for 214. In a further embodiment, electrode 204 can comprise a material such as niobium, tantalum, titanium nitride, niobium nitride or rhenium.

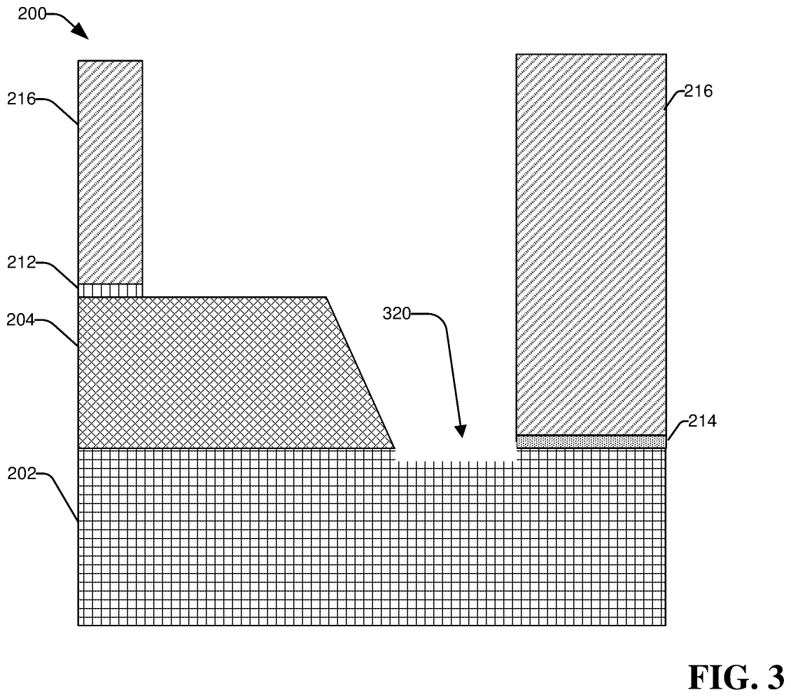

FIG. 3 illustrates a second stage of fabrication of a device 200 in accordance with one or more embodiments described herein. At this stage, an ion milling process can be utilized in cavity 220 to remove a portion of first oxide mask 212 and second oxide mask 214. Accordingly, this ion milling process exposes a portion of electrode 204 and creates cavity 320 which exposes a portion of substrate 202.

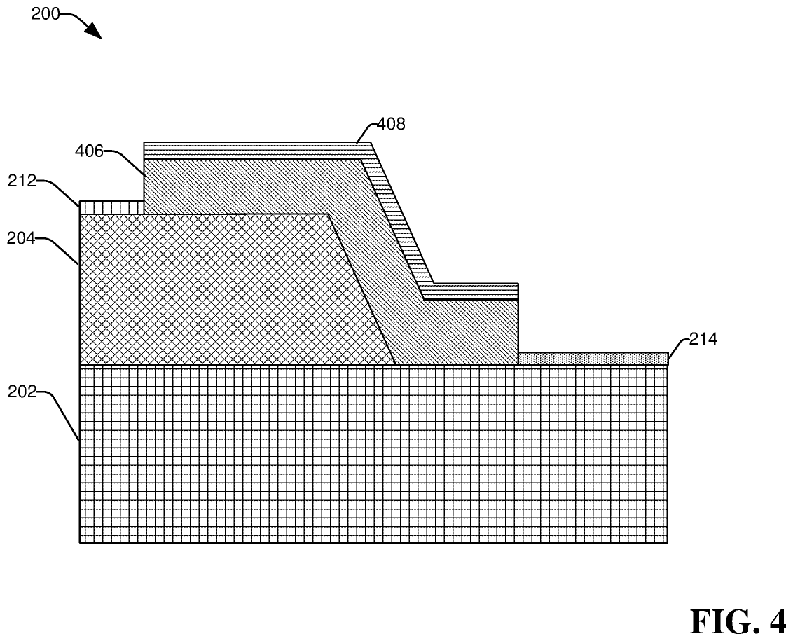

FIG. 4 illustrates a third stage of fabrication of device 200 in accordance with one or more embodiments described herein. At this stage, a metal deposition process can be utilized to deposit first contact layer 406 and second contact layer 408 into cavity 220 onto the exposed portions of electrode 204 and substrate 202. First photoresist layer 216 can then be removed in order to expose the remaining portion of first oxide mask 212 and second oxide mask 214. In an embodiment, first contact layer 406 can comprise a thickness between 20 nm and 100 nm, and second contact layer 408 can comprise a thickness between 1 nm and 20 nm. In an embodiment, first contact layer 406 can comprise a superconducting material such as, but not limited to, aluminum, vanadium, titanium nitride, niobium, tantalum, or rhenium and the second contact layer 408 can comprise an inert conductor material such as, but not limited to, platinum, iridium, rhenium, gold or palladium. As second contact layer 408 is formed from an inert material, second contact layer 408 acts as a protective layer for first contact layer 406 preventing oxidation.

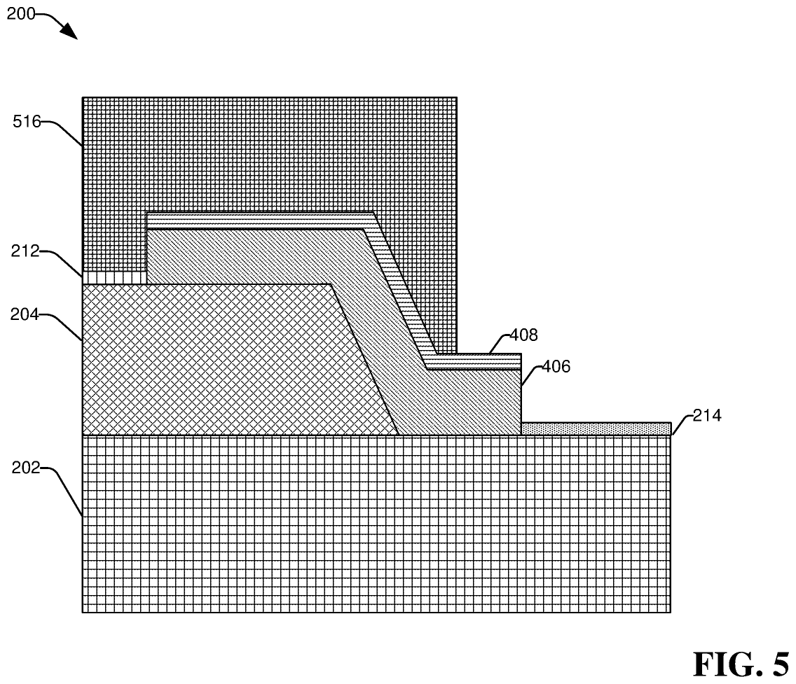

FIG. 5 illustrates a fourth stage of fabrication of device 200 in accordance with one or more embodiments described herein. At this stage, a second photoresist layer 516 can be coated onto first oxide mask 212 and second contact layer 408. A lithography step, (e.g., with an electron beam lithography), is used to open a portion of second contact layer 408, a side wall of first contact layer 406 and second oxide mask 214.

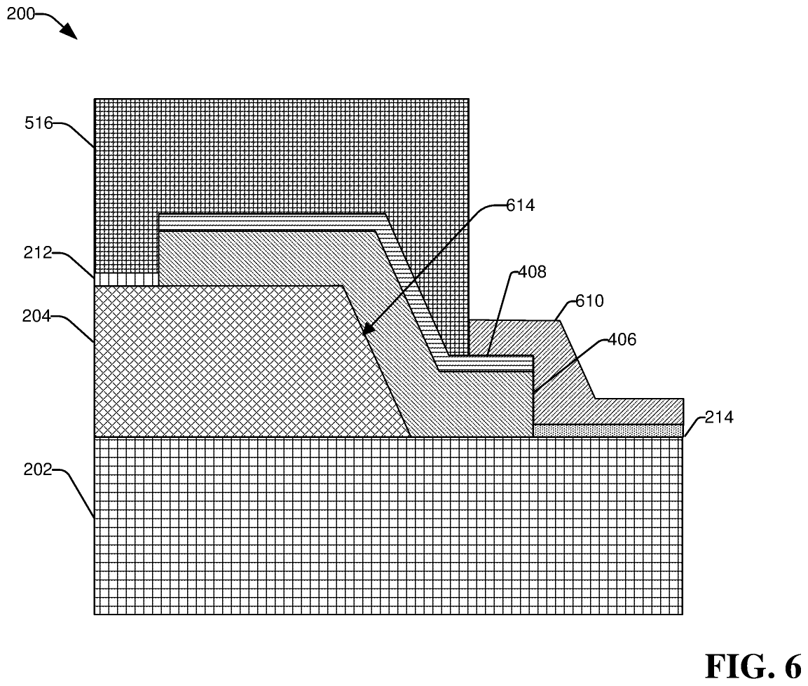

FIG. 6 illustrates a fifth stage of fabrication of device 200 in accordance with one or more embodiments described herein. At this stage, a metal deposition process can be utilized to deposit Josephson junction lead 610 onto the exposed portions of second contact layer 408. first contact layer 406 and second oxide mask 214. The metal deposition process can comprise an evaporation process, a chemical vapor deposition process, a molecular beam epitaxy process, an electron beam physical vapor deposition process, or any suitable deposition process. As the remaining portion of second oxide mask 214 was not exposed to ion milling, junction lead 610 is not impacted by any debris left by the process. Furthermore, as sidewall 614 of electrode 204 is covered by first contact layer 406, the thickness of junction lead 610 can be selected independent of the requirement to cover sidewall 614, leading to junction leads with thicknesses selected solely based on performance considerations. In an embodiment, junction lead 610 can comprise a superconducting material such as, but not limited to aluminum or vanadium.

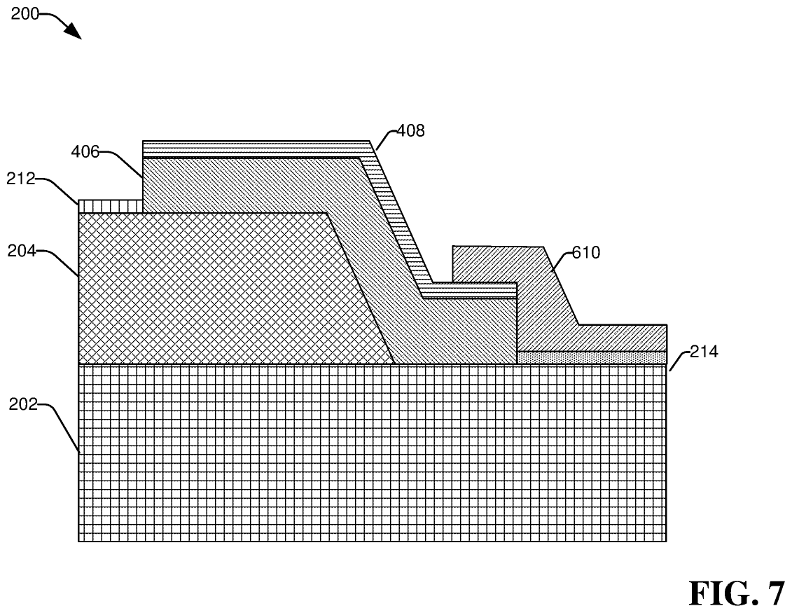

FIG. 7 illustrates a sixth stage of fabrication of device 200 in accordance with one or more embodiments described herein. At this stage, second photoresist layer 516 can be removed. It should be appreciated that due to the relative thinness of second contact layer 408 and the proximity of junction lead 610 and first contact layer 406, second contact layer 408 will superconduct when in operation.

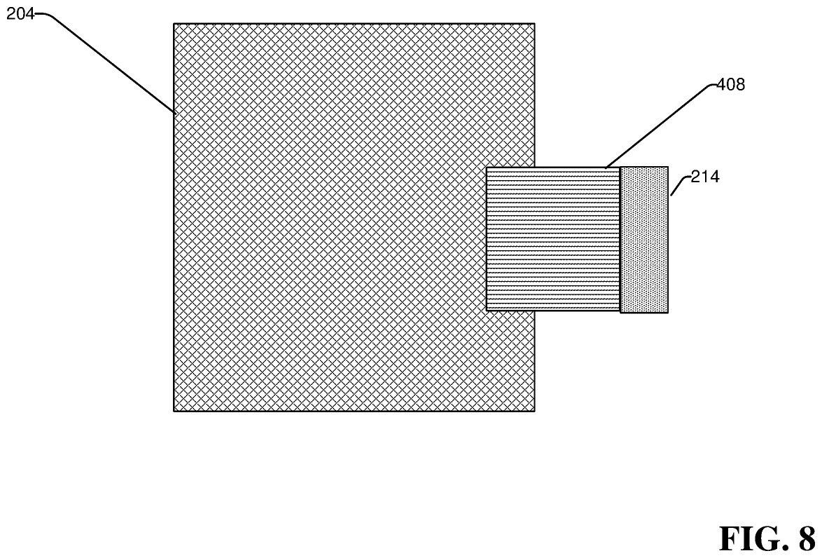

FIG. 8 illustrates a top-down view of a device 200 in accordance with one or more embodiments described herein. As shown, FIG. 8 corresponds to a top-down view of the cross section illustrated in FIG. 4. Accordingly, second contact layer 408 (and first contact layer 406 hidden below second contact layer 408) have been deposited onto electrode 204.

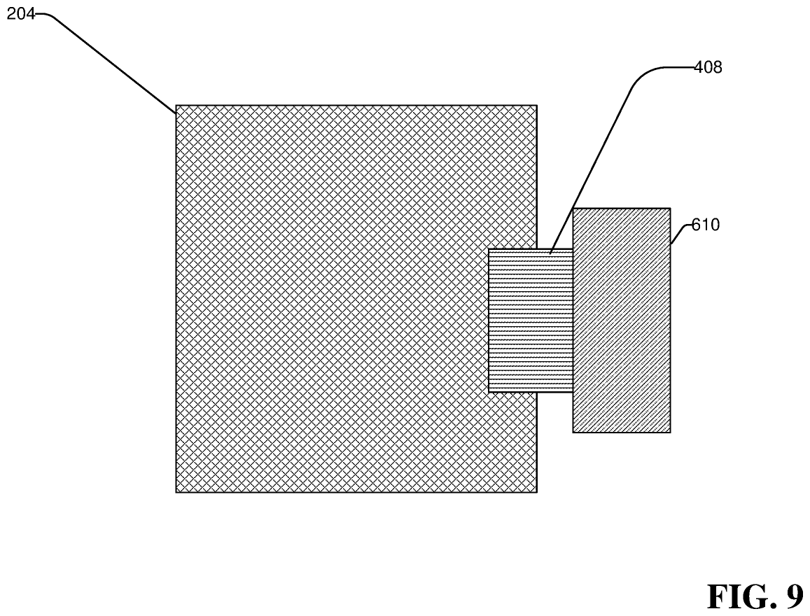

FIG. 9 illustrates a top-down view of device 200 in accordance with one or more embodiments described herein. As shown, FIG. 9 corresponds to a top-down view of the cross section illustrated in FIG. 6. Accordingly, junction lead 610 has been deposited onto a portion of second contact layer 408.

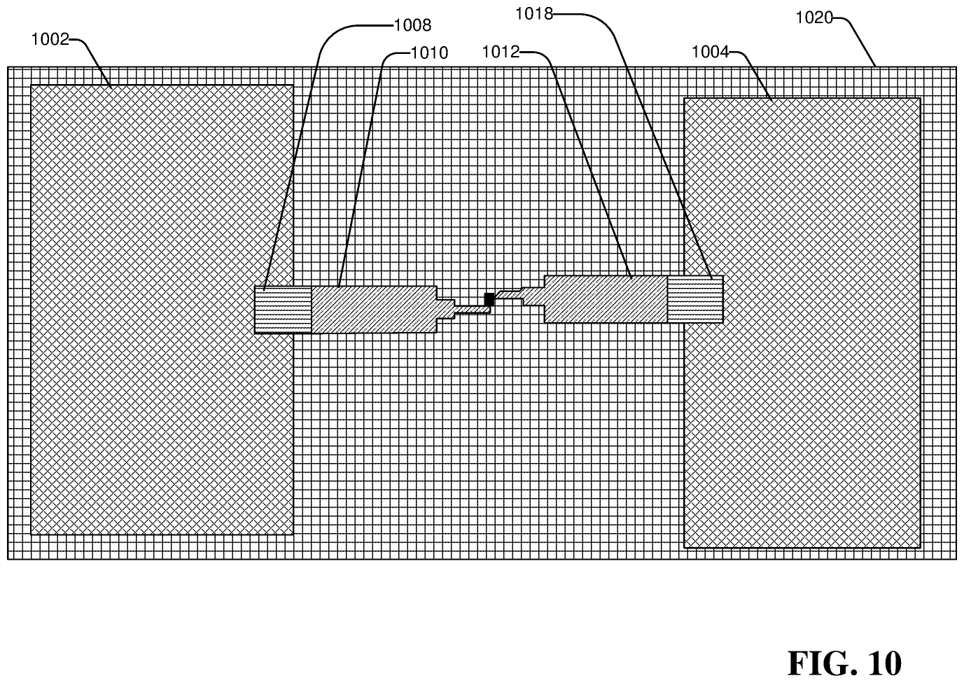

FIG. 10 illustrates an example qubit device 1000 with improved Josephson junction contacts in accordance with one or more embodiments described herein.

As shown, device 1000 comprises a first capacitor pad 1002 (e.g., an electrode) located on substrate 1020, a first contact 1008 located in direct contact with a top surface of first capacitor pad 1002, wherein first contact 1008 extends from the top surface of first capacitor pad 1002 to the top surface of substrate 1020. Device 1000 further comprises a second contact 1018 located in direct contact with a top surface of second capacitor pad 1004, wherein first contact 1018 extends from the top surface of second capacitor pad 1004 to the top surface of substrate 1020. Device 1000 additionally comprises a Josephson junction extending from first contact 1008 to second contact 1018, wherein the junction comprises a first junction lead 1010 and a second junction lead 1012. In an embodiment, both first contact 1008 and second contact 1018 can comprise first contact layers and second contact layers, wherein the first contact layers comprise a superconducting material and the second contact layers comprise an inert conductor material.

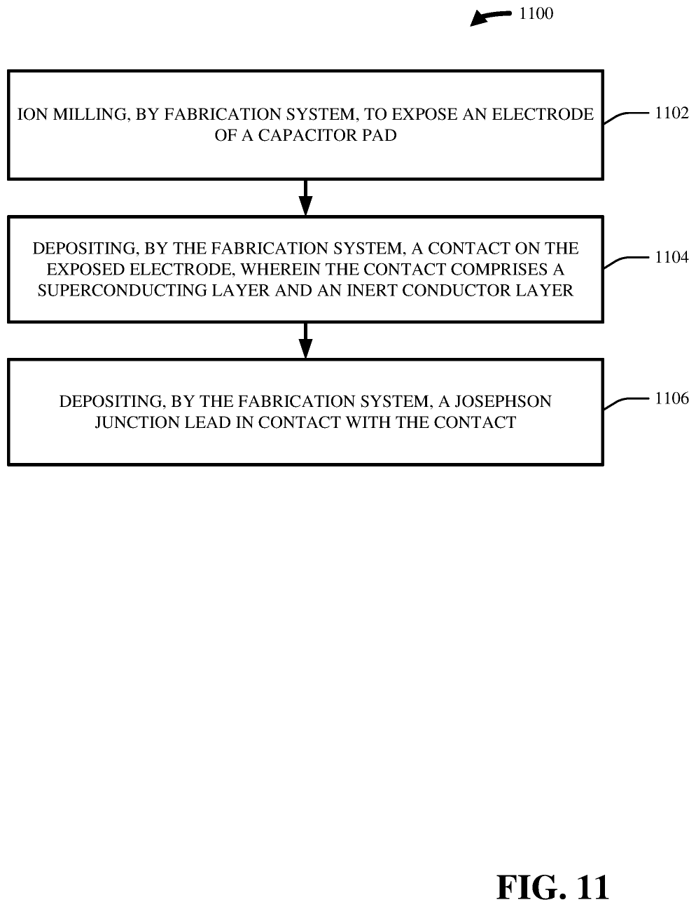

FIG. 11 illustrates a flow diagram of an example, non-limiting method of fabrication 1100 of a Josephson junction with improved contacts in accordance with one or more embodiments described herein.

At 1102, method 1100 can comprise, ion milling, by a fabrication system, to expose an electrode (e.g., electrode 204) of a capacitor pad. For example, as described above in reference to FIGS. 2-10, an ion milling process can be utilized to remove an oxide layer (e.g., first oxide mask 212) from at least a portion of the surface of the electrode. The electrode can comprise a material such as niobium, tantalum, titanium nitride, niobium nitride, or rhenium and a thickness of between 50 nm and 300 nm.

At 1104, method 1100 can comprise depositing, by the fabrication system, a contact on the exposed electrode, wherein the contact comprises a superconducting layer (e.g., first contact layer 406) and an inert conductor layer (e.g., second contact layer 408). For example, as described above in reference to FIGS. 2-10, the inert conductor layer can be deposited on top of the superconducting layer, wherein the superconducting layer comprises a thickness between 20 nm and 100 nm, and wherein the inert conductor layer comprises a thickness between 1 nm and 20 nm. Furthermore, the superconducting layer can comprise a material such as aluminum, vanadium, titanium nitride, niobium, tantalum, or rhenium and the inert conductor layer can comprise a material such as platinum, iridium, rhenium, gold, or palladium.

At 1106, method 1100 can comprise depositing, by the fabrication system, a Josephson junction lead (e.g., junction lead 610) in contact with the contact (e.g., second contact layer 408. For example, as described above junction lead 610 can be deposited in contact with a top surface of second contact layer 408, and the relative thinness of second contact layer 408 will allow for superconducting coupling between first contact layer 406 and junction lead 610.

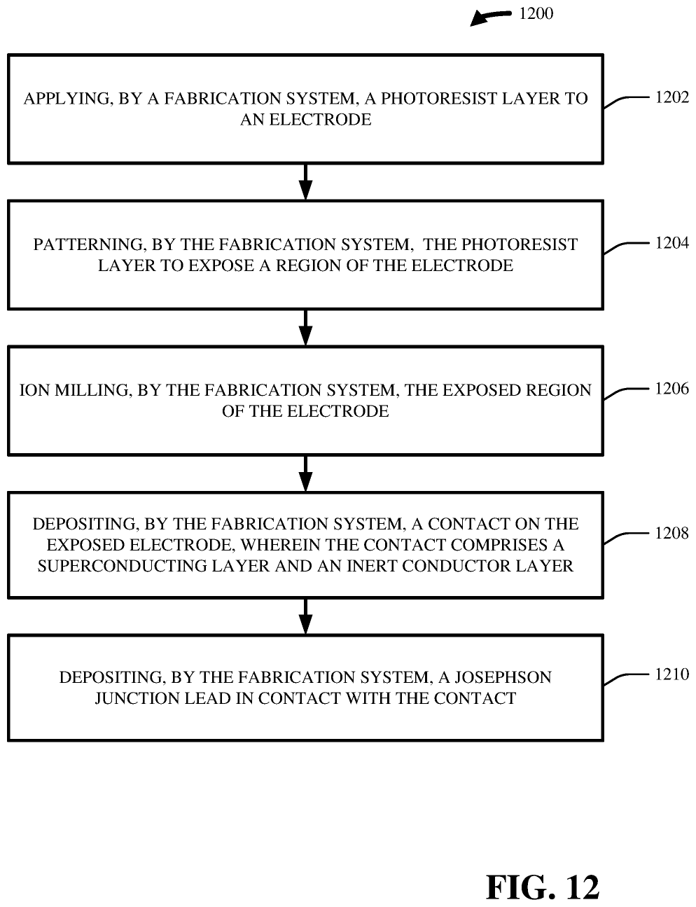

FIG. 12 illustrates a flow diagram of an example, non-limiting method of fabrication 1200 of a Josephson junction with improved contacts in accordance with one or more embodiments described herein.

At 1202, method 1200 can comprise applying, by a fabrication system, a photoresist layer (e.g., photoresist layer 216) to an electrode (e.g., electrode 204).

At 1204, method 1200 can comprise patterning (e.g., cavity 220), by the fabrication system, the photoresist layer (e.g., photoresist layer 216) to expose a region of the electrode.

At 1206, method 1200 can comprise ion milling, by the fabrication system, the exposed region of the electrode. For example, as described above in reference to FIGS. 2-10, an ion milling process can be utilized to remove an oxide layer (e.g., first oxide mask 212) from the exposed portion of the surface of the electrode. The electrode can comprise a material such as niobium, tantalum, titanium nitride, niobium nitride, or rhenium and a thickness of between 50 and 300 nm.

At 1208, method 1200 can comprise depositing, by the fabrication system, a contact on the exposed electrode, wherein the contact comprises a superconducting layer and an inert conductor layer. For example, as described above in reference to FIGS. 2-10, the inert conductor layer can be deposited on top of the superconducting layer, wherein the superconducting layer comprises a thickness between 20 nm and 100 nm, and wherein the inert conductor layer comprises a thickness between 1 nm and 20 nm. Furthermore, the superconducting layer can comprise a material such as aluminum, vanadium, titanium nitride, niobium, tantalum, or rhenium and the inert conductor layer can comprise a material such as platinum, iridium, rhenium, gold, or palladium.

At 1210, method 1200 can comprise depositing, by the fabrication system, a Josephson junction lead (e.g., junction lead 610) in contact with the contact (e.g., second contact layer 408. For example, as described above junction lead 610 can be deposited in contact with a top surface of second contact layer 408, and the relative thinness of second contact layer 408 will allow for superconducting coupling between first contact layer 406 and junction lead 610.

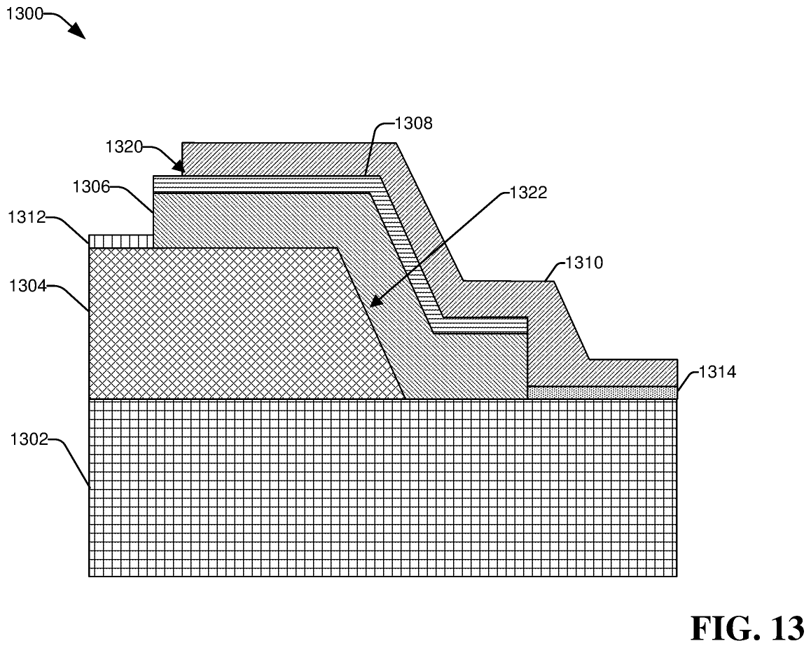

FIG. 13 cross-section view of a device 1300 comprising an improved contact for a Josephson junction in accordance with one or more embodiments described herein.

As shown, device 1300 comprises an electrode 1304 on top of a substrate 1302, a first contact layer 1306 on top of electrode 1304 (alternatively referred to as a capacitor pad), a second contact layer 1308 on top of first contact layer 1306, and a Josephson junction lead 1310 in direct contact with both first contact layer 1306 and second contact layer 1308, similar to that of device 100 described above in relation to FIG. 1. However, as shown in FIG. 13, junction lead 1310 can extend unto an upper portion 1320 of second contact layer 1308. In one or more embodiments, the length of junction lead 1310 and how far it extends over second contact layer 1308 can be based on the intended performance characteristics of the Josephson junction. As first contact layer 1306 is used to cover sidewall 1322 of electrode 1304, the thickness of junction 1310 can be independent of the requirement to cover electrode 1304, junction thickness can be selected in order to improve performance and coherence. Further, as layer 1314 separates junction 1310 from substrate 1302, performance losses due to ion milling of the substrate 1302 as avoided, thus improving junction performance.

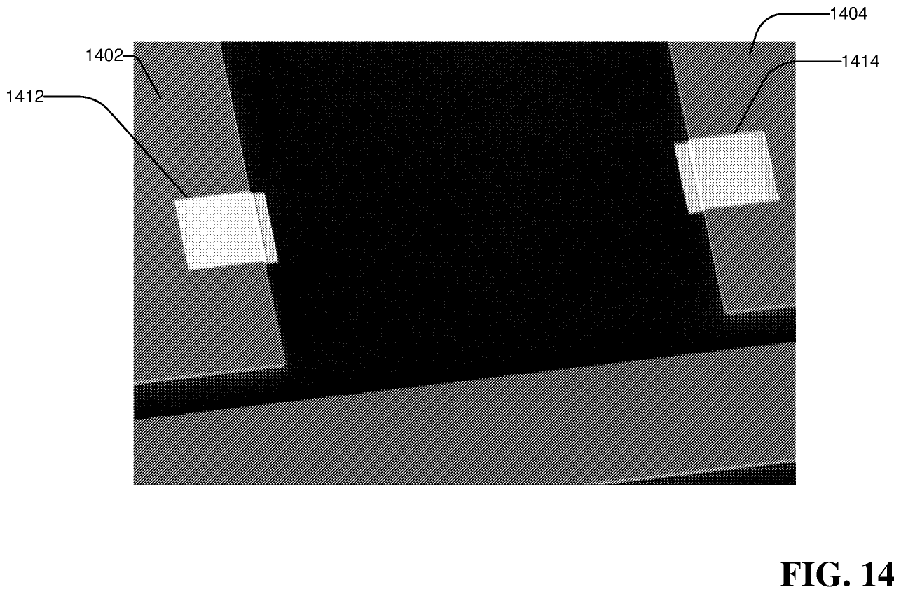

FIG. 14 illustrates an image of a device 1400 comprising improved contacts in accordance with one or more embodiments described herein.

As shown, device 1400 comprises a first capacitor pad 1402, a second capacitor pad 1404, a first contact 1412 located on the surface of first capacitor pad 1402 and a second contact 1414 located on the surface of second capacitor pad 1404. Both first contact 1412 and second contact 1414 comprise a first contact layer comprising a superconducting material and a second contact layer comprising an inert conductor material, wherein the second contact layer is located on the top surface of the first contact layer. It should further be appreciated that the first contact 1412 and the second contact 1414 extend from the surface of the respective capacitor pads onto the substrate on which the capacitor pads are located.

Fabrication of the various embodiments of the subject disclosure described herein and/or illustrated in the figures (e.g., device 100, device 400, device 500, etc.) can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, the various embodiments of the subject disclosure described herein and/or illustrated in the figures (e.g., device 100, device 400, device 500, etc.) can be fabricated on a substrate (e.g., a silicon (Si) substrate, etc.) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, etc.), etching techniques (e.g., reactive ion etching (RIE), dry etching, wet etching, ion beam etching, plasma etching, laser ablation, etc.), evaporation techniques, sputtering techniques, plasma ashing techniques, thermal treatments (e.g., rapid thermal anneal, furnace anneals, thermal oxidation, etc.), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

The various embodiments of the subject disclosure described herein and/or illustrated in the figures (e.g., device 100, device 400, device 500, etc.) can be fabricated using various materials. For example, the various embodiments of the subject disclosure described herein and/or illustrated in the figures (e.g., device 100, device 400, device 500, etc.) can be fabricated using materials of one or more different material classes including, but not limited to: conductive materials, semiconducting materials, superconducting materials, dielectric materials, polymer materials, organic materials, inorganic materials, non-conductive materials, and/or another material that can be utilized with one or more of the techniques described above for fabricating an integrated circuit.

An advantage of the devices described herein is that they enable production of quantum computing systems with improved performance. For example, by enabling the use of different thickness of junction leads, the performance of the quantum elements (e.g., coherence and tunability) can be improved, thereby leading to improved performance of quantum systems utilizing the quantum elements.

A practical application of the devices described herein is that they allow for selection of junction lead thicknesses that are independent of the thickness called for to cover the side wall of an electrode. This allows for selection of junction thicknesses based solely on concerns such as tunability of the qubits produced, and improving coherence, thereby improving performance of the quantum elements. Furthermore, the devices described above allow for decreases in the amount of ion milling used during fabrication, thereby limiting the damage caused to substrates and debris associated with ion milling, further improving device performance.

The descriptions of the various embodiments have been presented for purposes of illustration but are not intended to be exhaustive or limited to the embodiments described herein. Many modifications and variations will be apparent to those of ordinary skill in the art without departing from the scope and spirit of the described embodiments. The terminology used herein was chosen to best explain the principles of the embodiments, the practical application and/or technical improvement over technologies found in the marketplace, and/or to enable others of ordinary skill in the art to understand the embodiments described herein.

What is claimed is:

1. A device comprising:
a superconducting capacitor pad located on top of a substrate;
a contact located on a top surface of the capacitor pad, wherein the contact comprises a first contact layer comprising a superconducting material and in direct contact with the capacitor pad and a second contact layer comprising an inert conductor and that is located on top of the first contact layer; and
a Josephson junction in contact with the contact.

2. The device of claim 1, wherein the direct contact was formed using ion milling to remove surface oxide prior to deposition of the first contact layer, such that the first contact layer makes contact with the clean surface of the capacitor pad.

3. The device of claim 1, wherein the first contact layer comprises at least one of aluminum, vanadium, titanium nitride, niobium, tantalum, or rhenium.

4. The device of claim 1, wherein the second contact layer comprises at least one of platinum, iridium, rhenium, gold, or palladium.

5. The device of claim 1, wherein the capacitor pad comprises at least one of niobium, tantalum, titanium nitride, niobium nitride or rhenium.

6. The device of claim 1, wherein the first contact layer comprises a thickness greater than a thickness of the second contact layer, and wherein the second contact layer comprises a thickness that allows for superconducting of the second contact layer due to proximity of the first contact layer and the Josephson junction.

7. The device of claim 1, wherein the first contact layer comprises a thickness between 20 nm and 100 nm.

8. The device of claim 1, wherein the second contact layer comprises a thickness between 1 nm and 20 nm.

9. The device of claim 1, wherein the electrode comprises a thickness between 50 nm and 300 nm.

10. A method of fabricating a device, by a fabrication system, comprising:
ion milling, by the fabrication system, to expose an electrode of a capacitor pad;
depositing, by the fabrication system, a contact on the exposed electrode, wherein the contact comprises a first contact layer comprising a superconducting material and a second contact layer comprising an inert conductor material located on top of the first contact layer; and
depositing, by the fabrication system, a Josephson junction in contact with the contact.

11. The method of claim 10, wherein the first contact layer comprises at least one of aluminum, vanadium, titanium nitride, niobium, tantalum, or rhenium.

12. The method of claim 10, wherein the second contact layer comprises at least one of platinum, iridium, rhenium, gold or palladium.

13. The method of claim 10, wherein the capacitor pad comprises at least one of niobium, tantalum, titanium nitride, niobium nitride or rhenium.

14. The method of claim 10, wherein the first contact layer comprises a thickness between 20 nm and 100 nm, and wherein the second contact layer comprises a thickness between 1 nm and 20 nm.

15. The method of claim 10, wherein the ion milling comprises:
applying, by the fabrication system, a first photoresist layer to the electrode;
patterning, by the fabrication system the first photoresist layer to expose a region of the electrode; and
ion milling, by the fabrication system, the exposed region of the electrode.

16. The method of claim 10, wherein the first contact layer comprises a thickness greater than a thickness of the second contact layer, and wherein the thickness of the second contact layer allows for super conducting of the second contact layer due to proximity of the first contact layer and the Josephson junction.

17. A device comprising:
a first capacitor pad located on a substrate;
a first contact located in direct contact with a top surface of the first capacitor pad, wherein the first contact extends from the top surface of the first capacitor pad to a top surface of the substrate;
a second capacitor pad located on a substrate;
a second contact located in direct contact with a top surface of the second capacitor pad, wherein the second contact extends from the top surface of the capacitor pad to the top surface of the substrate; and
a Josephson junction extending from the first contact to the second contact.

18. The device of claim 17, wherein the first contact comprises a superconducting layer and an inert conductor layer located on top of the superconducting layer.

19. The device of claim 18, wherein the second contact comprises a second superconducting layer and a second inert conductor layer located on top of the superconducting layer.

20. The device of claim 18, wherein the superconducting layer comprises a thickness greater than a thickness of the inert conductor layer, and wherein the inert conductor layer comprises a thickness that allows for superconducting of the inert conductor layer due to proximity of the superconducting layer and the Josephson junction.
